(19) United States
(12) Patent Application Publication
(10) Pub. No.: US 2024/0178880 A1
(43) Pub. Date: May 30, 2024

(54) TRANSMISSION SYSTEM

(71) Applicant: Mitsubishi Electric Corporation, Chiyoda-ku, (JP)

(72) Inventor: Takehiko KUBOTA, Tokyo (JP)

(73) Assignee: Mitsubishi Electric Corporation, Tokyo (JP)

(21) Appl. No.: 18/284,069

(22) PCT Filed: Apr. 1, 2021
(86) PCT No.: PCT/JP2021/014241

§ 371 Date: Sep. 26, 2023

(51) Int. Cl. H04B 3/06; B66B 1/34; H03K 3/01

(52) U.S. Cl. CPC H04B 3/06; B66B 1/3461; H03K 3/01

(57) ABSTRACT

To provide a transmission system capable of ensuring reliability of signal transmission. The transmission system includes: a remote unit alternately outputting pulse voltage with a positive polarity and pulse voltage with a negative polarity as a signal by causing a first switching element and a second switching element to alternately open and close; and a master unit accepting input of a signal from the remote unit via a cable, and separating the signal into a first signal corresponding to the pulse voltage with the positive polarity and a second signal corresponding to the pulse voltage with the negative polarity.

### TECHNICAL FIELD

The present disclosure relates to a transmission system.

### BACKGROUND ART

PTL 1 discloses an elevator. In the elevator, a car goes up and down inside a hoistway.

### PRIOR ART

### Patent Literature

[PTL 1] JP 2018-34977 A

### SUMMARY OF THE INVENTION

### Problem to be Solved by the Invention

In the car described in PTL 1, various signals related to completeness are outputted to a control apparatus. Therefore, reliability of signal transmission is required.

The present disclosure has been made to solve the above problem. An object of the present disclosure is to provide a transmission system capable of ensuring reliability of signal transmission.

### Means to Solve the Problem

A transmission system according to the present disclosure includes: a remote unit alternately outputting pulse voltage with a positive polarity and pulse voltage with a negative polarity as a signal by causing a first switching element and a second switching element to alternately open and close; and a master unit accepting input of a signal from the remote unit via a cable, and separating the signal into a first signal corresponding to the pulse voltage with the positive polarity and a second signal corresponding to the pulse voltage with the negative polarity.

### Effects of the Invention

According to the present disclosure, a remote unit alternately outputs pulse voltage with a positive polarity and pulse voltage with a negative polarity as a signal by causing a first switching element and a second switching element to alternately open and close. A master unit accepts input of a signal from the remote unit, and separates the signal into a first signal corresponding to the pulse voltage with the positive polarity and a second signal corresponding to the pulse voltage with the negative polarity. Therefore, it is possible to ensure reliability of signal transmission.

### BRIEF DESCRIPTION OF DRAWINGS

FIG. 1 is a configuration diagram of an elevator system to which a transmission system in a first embodiment is applied.

FIG. 2 is a configuration diagram of the transmission system in the first embodiment.

FIG. 3 is a diagram showing operation instructions to a first switching element and a second switching element by a remote unit of the transmission system in the first embodiment.

FIG. 4 is a diagram showing output voltage of the remote unit of the transmission system in the first embodiment.

FIG. 5 is a diagram showing operation instructions to the first switching element and the second switching element by the remote unit of the transmission system in the first embodiment.

FIG. 6 is a diagram showing first and second signals of a master unit of the transmission system in the first embodiment.

FIG. 7 is a hardware configuration diagram of a first remote-side control circuit of the transmission system in the first embodiment.

### DESCRIPTION OF EMBODIMENTS

An embodiment will be described according to accompanying drawings. In the drawings, the same or corresponding portions will be given the same reference sign. Duplicated description of the portions will be appropriately simplified or omitted.

### First Embodiment

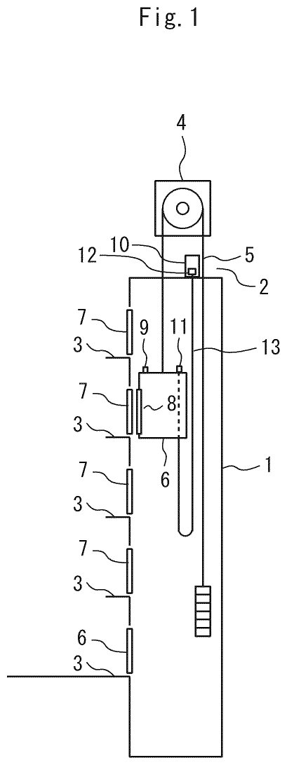

FIG. 1 is a configuration diagram of an elevator system to which a transmission system in a first embodiment is applied.

In the elevator system of FIG. 1, a hoistway 1 runs through floors of a building not shown. A machine room 2 is provided right above the hoistway 1. A plurality of halls 3 are provided on the floors of the building, respectively. Each of the plurality of halls 3 faces the hoistway 1.

A traction machine 4 is provided in the machine room 2. A main rope 5 is wrapped around the traction machine 4.

A car 6 is provided inside the hoistway 1. The car 6 is supported on one side of the main rope 5. A counterweight is provided inside the hoistway 1. The counterweight is supported on the other side of the main rope 5.

A plurality of hall doors 7 are provided at doorways at the plurality of halls 3, respectively. A car door 8 is provided at the doorway of the car 6.

A safety apparatus 9 is provided on the car 6. The safety apparatus 9 includes a car door opening detection device, an on-car stopping device, an emergency stop detection device, a car position detection device for detecting door-opened car movement and the like.

A control apparatus 10 is provided in the machine room 2.

The transmission system is provided with a remote unit 11, a master unit 12 and cables 13.

The remote unit 11 is provided on the car 6 as a programmable electronic safety apparatus. The remote unit 11 is electrically connected to the safety apparatus. The master unit 12 is provided in the control apparatus 10 as a programmable electronic safety apparatus. The cables 13 electrically connect the remote unit 11 and the master unit 12.

The control apparatus 10 causes the traction machine 4 to rotate during operation of the elevator. The main rope 5 moves, following the rotation of the traction machine 4. The car 6 and the counterweight go up and down in mutually opposite directions, following the movement of the main rope 5.

When an abnormality occurs during operation of the elevator, the safety apparatus 9 outputs an abnormality signal. The remote unit 11 accepts input of the abnormality signal from the safety apparatus 9. The remote unit 11 outputs a signal corresponding to the abnormality signal. The master unit 12 accepts input of the signal from the remote unit 11 via the cables 13.

The control apparatus 10 detects the abnormality based on the signal inputted to the master unit 12. When the abnormality is detected, the control apparatus 10 stops rotation of the traction machine 4. The main rope 5 stops movement, following the stop of rotation of the traction machine 4. The car 6 and the counterweight stop going up and down, following the stop of movement of the main rope 5.

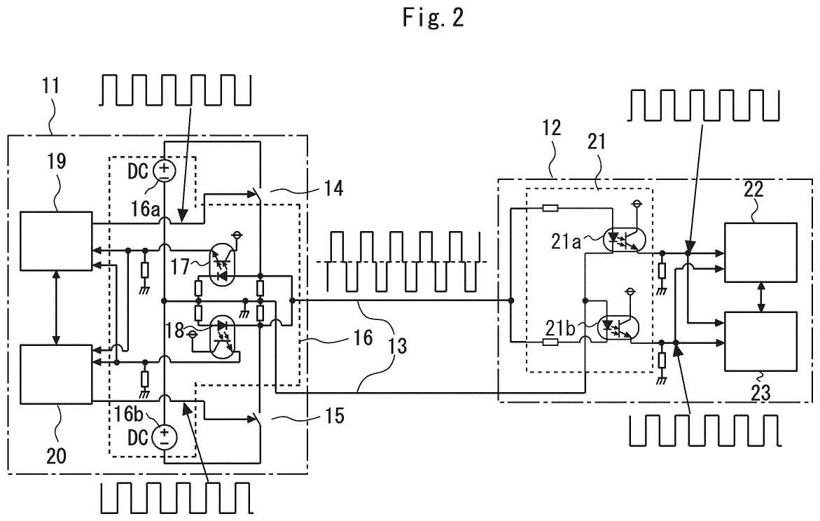

Next, the remote unit 11 and the master unit 12 will be described using FIG. 2.

FIG. 2 is a configuration diagram of the transmission system in the first embodiment.

As shown in FIG. 2, the remote unit 11 is provided with a first switching element 14, a second switching element 15, a signal output circuit 16, a positive-side insulation signal element 17, a negative-side insulation signal element 18, a first remote-side control circuit 19 and a second remote-side control circuit 20.

The first switching element 14 is provided, being capable of opening and closing. The second switching element 15 is provided, being capable of opening and closing.

The signal output circuit 16 is provided with a positive-side power supply 16a and a negative-side power supply 16b. The signal output circuit 16 is provided, being capable of, when the first switching element 14 is closed, outputting pulse voltage with a positive polarity as a signal using power of the positive-side power supply 16a. The signal output circuit 16 is provided, being capable of, when the second switching element 15 is closed, outputting pulse voltage with a negative polarity as a signal using power of the negative-side power supply 16b.

For example, the positive-side insulation signal element 17 is a photo coupler. The positive-side insulation signal element 17 is provided, being capable of outputting a signal corresponding to an open/close state of the first switching element 14.

For example, the negative-side insulation signal element 18 is a photo coupler. The negative-side insulation signal element 18 is provided, being capable of outputting a signal corresponding to the open/close state of the first switching element 14.

The first remote-side control circuit 19 and the second remote-side control circuit 20 are independent of each other. The first remote-side control circuit 19 and the second remote-side control circuit 20 are not synchronized using the same clock or the like.

The first remote-side control circuit 19 and the second remote-side control circuit 20 operate so that the first switching element 14 and the second switching element 15 mutually alternately open and close. Specifically, the first remote-side control circuit 19 controls opening/closing of the first switching element 14 so that the first switching element 14 and the second switching element 15 mutually alternately open and close. The second remote-side control circuit 20 controls opening/closing of the second switching element 15 so that the first switching element 14 and the second switching element 15 mutually alternately open and close.

The first remote-side control circuit 19 monitors the open/close state of the first switching element 14 based on a signal from the positive-side insulation signal element 17. The first remote-side control circuit 19 monitors the open/close state of the second switching element 15 based on a signal from the negative-side insulation signal element 18.

The second remote-side control circuit 20 monitors the open/close state of the first switching element 14 based on a signal from the positive-side insulation signal element 17. The second remote-side control circuit 20 monitors the open/close state of the second switching element 15 based on a signal from the negative-side insulation signal element 18.

The master unit 12 is provided with a signal separation circuit 21, a first master-side control circuit 22 and a second master-side control circuit 23.

The signal separation circuit 21 is provided with a first separation element 21a and a second separation element 21b. The first separation element 21a generates a first signal corresponding to the pulse voltage with the positive polarity, from a signal from the remote unit 11, using the polarity of a light emitting diode included in the photo coupler. The second separation element 21b generates a second signal corresponding to the pulse voltage with the negative polarity, from a signal from the remote unit 11, using the polarity of a light emitting diode included in the photo coupler.

The first master-side control circuit 22 monitors the first and second signals from the signal separation circuit 21.

The second master-side control circuit 23 monitors the first and second signals from the signal separation circuit 21.

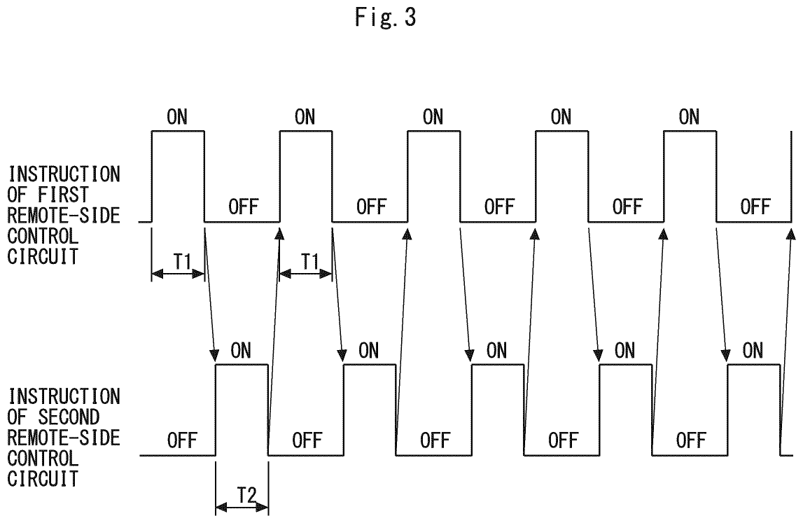

Next, operations of the first remote-side control circuit 19 and the second remote-side control circuit 20 will be described using FIG. 3.

FIG. 3 is a diagram showing operation instructions to the first switching element and the second switching element by the remote unit of the transmission system in the first embodiment.

As shown in FIG. 3, the first remote-side control circuit 19 outputs an operation instruction to the first switching element 14 and, after a first operation time T1 set in advance passes, stops the operation instruction to the first switching element 14. The second remote-side control circuit 20 outputs an operation instruction to the second switching element 15 when detecting that the first switching element 14 has opened and, after a second operation time T2 set in advance passes, stops the operation instruction to the second switching element 15. The first remote-side control circuit 19 outputs an operation instruction to the first switching element 14 when detecting that the second switching element 15 has opened and, after the first operation time T1 passes, stops the operation instruction to the first switching element 14.

These operations are repeated. As a result, the first switching element 14 and the second switching element 15 alternately open and close.

In FIG. 3, the first operation time T1 and the second operation time T2 are the same. The first operation time T1 and the second operation time T2 may be different.

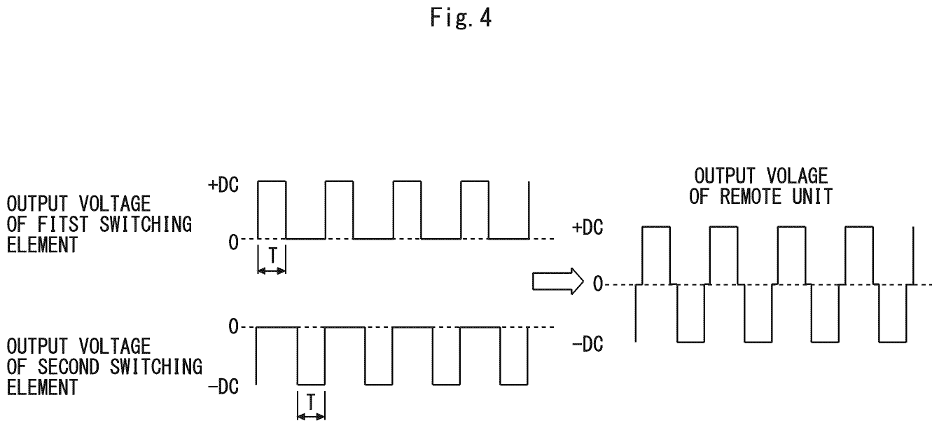

Next, output voltage of the remote unit 11 will be described using FIG. 4.

FIG. 4 is a diagram showing the output voltage of the remote unit of the transmission system in the first embodiment.

As shown on the upper part on the left side of FIG. 4, output voltage of the first switching element 14 is pulse voltage with the positive polarity. As shown on the lower part on the left side of FIG. 4, output voltage of the second switching element 15 is pulse voltage with the negative polarity. As a result, as for the output voltage of the remote unit 11, the pulse voltage with the positive polarity and the pulse voltage with the negative polarity alternately appear as a signal as shown on the right side of FIG. 4.

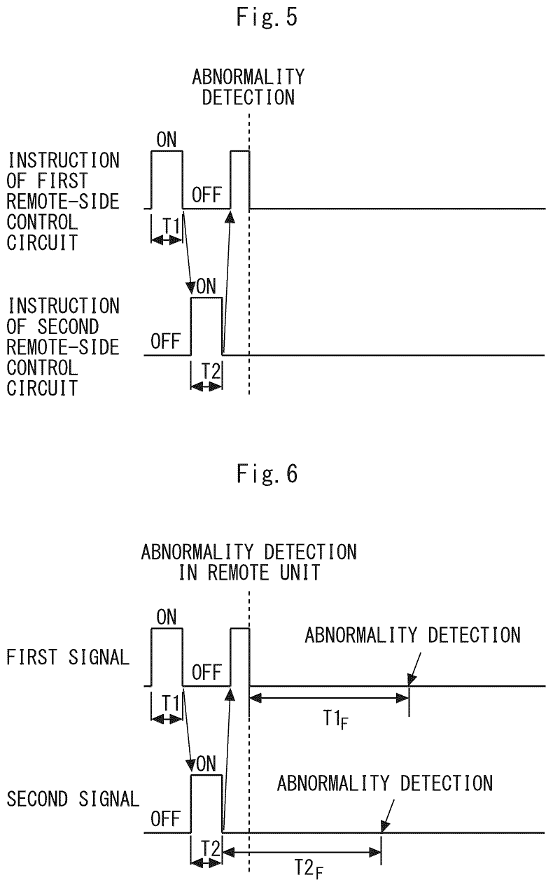

Next, operation of the remote unit 11 when an abnormality is detected will be described using FIG. 5.

FIG. 5 is a diagram showing operation instructions to the first switching element and the second switching element by the remote unit of the transmission system in the first embodiment.

As shown in FIG. 5, when operation of the safety apparatus 9 is detected, a first remote-side monitoring apparatus maintains a state of the operation instruction to the first switching element 14 being stopped. A second remote-side monitoring apparatus maintains a state of the operation instruction to the second switching element 15 being stopped.

Next, detection of an abnormality by the master unit 12 will be described using FIG. 6.

FIG. 6 is a diagram showing the first and second signals of the master unit of the transmission system in the first embodiment.

As shown in FIG. 6, if the first signal corresponding to the pulse voltage with the positive polarity is not detected during a time obtained by adding a first spare time T1_{F} set in advance to the first operation time T1, the first master-side control circuit 22 and the second master-side control circuit 23 detect an abnormality. If the second signal corresponding to the pulse voltage with the negative polarity is not detected during a time obtained by adding a second spare time T2_{F} set in advance to the second operation time T2, the first master-side control circuit 22 and the second master-side control circuit 23 detect an abnormality.

The first spare time T1_{F} is several times as long as the first operation time T1. The second spare time T2_{F} is several times as long as the second operation time T2.

According to the first embodiment described above, the remote unit 11 alternately outputs the pulse voltage with the positive polarity and the pulse voltage with the negative polarity as a signal by causing the first switching element 14 and the second switching element 15 to alternately open and close. The master unit 12 accepts input of a signal from the remote unit 11, and separates the signal into the first signal corresponding to the pulse voltage with the positive polarity and the second signal corresponding to the pulse voltage with the negative polarity. At this time, the signal is not normally restored unless the first switching element 14 and the second switching element 15 normally open and close in the master unit 12. As a result, it is possible to, even if a transmission distance is long, ensure reliability of signal transmission.

In the transmission system of the first embodiment, a signal is simple in comparison with serial communication such as RSS-422 communication in which it is necessary to perform protection by a cyclic redundancy check (CRC) algorithm or the like to ensure consistency of safety signal data, and there is a possibility that the amount of transmission data increases. Therefore, the signal transmission speed is fast. As a result, it is possible to obtain necessary response time as means for transmitting a signal related to safety.

In the transmission system of the first embodiment, expensive cables such as twisted-pair wires used for serial communication are not necessary. Therefore, the transmission system can be constructed inexpensively. In the case of using serial communication such as RSS-422 communication, it is conceivable to reduce communication cables by including information other than a safety signal into a communication signal. In this case, however, it is difficult to separate the safety signal and signals different from the safety signal.

In the transmission system of the first embodiment, the number of cables 13 can be reduced in comparison with parallel wiring. Therefore, the transmission system can be constructed inexpensively.

Further, the first remote-side control circuit 19 controls opening/closing of the first switching element 14 so that the first switching element 14 and the second switching element 15 alternately open and close. The second remote-side control circuit 20 controls opening/closing of the second switching element 15 so that the first switching element 14 and the second switching element 15 alternately open and close. Therefore, it is possible to appropriately output a signal from the remote unit 11.

Further, the first remote-side control circuit 19 and the second remote-side control circuit 20 monitor the open/close states of the first switching element 14 and the second switching element 15. Therefore, it is possible to steadily detect a sticking failure of the first switching element 14 and the second switching element 15. As a result, it is possible to maintain a failure rate required for the remote unit 11 without stopping the elevator.

Further, the first remote-side control circuit 19 closes the first switching element 14 when detecting that the second switching element 15 has opened and, after the first operation time set in advance passes, opens the first switching element 14. The second remote-side circuit closes the second switching element 15 when detecting that the first switching element 14 has opened and, after the second operation time set in advance passes, opens the second switching element 15. Therefore, even if the first remote-side control circuit 19 and the second remote-side control circuit 20 are not synchronized using the same clock or the like, it is possible to cause the first switching element 14 and the second switching element 15 to certainly alternately open and close.

The first remote-side control circuit 19 maintains the first switching element in an opened state when an abnormality is detected. The second remote-side control circuit 20 maintains the second switching element 15 in an opened state when an abnormality is detected. Therefore, it is possible to output a signal corresponding to the abnormality to the master unit 12 more certainly.

Further, the first master-side control circuit 22 and the second master-side control circuit 23 monitor the first signal corresponding to the pulse voltage with the positive polarity and the second signal corresponding to the pulse voltage with the negative polarity. Therefore, it is possible to ensure reliability of signal transmission more certainly.

Further, the first master-side control circuit 22 and the second master-side control circuit 23 detect an abnormality if the first signal is not detected during the time obtained by adding the first spare time to the first operation time or if the second signal is not detected during the time obtained by adding the second spare time to the second operation time. Therefore, it is possible to detect an abnormality in the master unit 12 more certainly.

The transmission system of the first embodiment may be applied to such an elevator that the machine room 2 is not provided, and the traction machine 4 and the control apparatus 10 are provided on the upper or lower part of the hoistway 1.

Further, the transmission system of the first embodiment may be applied to signal transmission other than signal transmission for an elevator system.

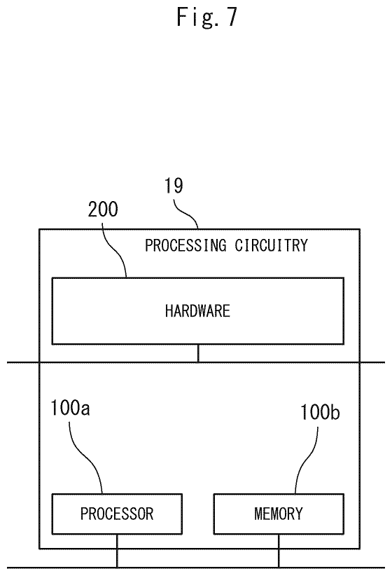

Next, an example of the first remote-side control circuit 19 will be described using FIG. 7.

FIG. 7 is a hardware configuration diagram of the first remote-side control circuit of the transmission system in the first embodiment.

Each function of the first remote-side control circuit 19 can be realized by a processing circuit. For example, the processing circuit is provided with at least one processor 100a and at least one memory 100b. For example, the processing circuit is provided with at least one piece of dedicated hardware 200.

When the processing circuit is provided with the at least one processor 100a and the at least one memory 100b, each function of the first remote-side control circuit 19 is realized by software, firmware or a combination of software and firmware. At least either the software or the firmware is written as a program. At least either the software or the firmware is stored in the at least one memory 100b. The at least one processor 100a realizes each function of the first remote-side control circuit 19 by reading and executing the program stored in the at least one memory 100b. The at least one processor 100a is also referred to as a central processing unit, a processing device, an arithmetic device, a microprocessor, a microcomputer or a DSP. The at least one memory 100b is, for example, a non-volatile or volatile semiconductor memory, such as a RAM, a ROM, a flash memory, an EPROM or an EEPROM, a magnetic disk, a flexible disk, an optical disc, a compact disc, a mini disc, a DVD or the like.

When the processing circuit is provided with the at least one piece of dedicated hardware 200, the processing circuit is realized, for example, by a single circuit, a composite circuit, a programmed processor, processors programmed in parallel, an ASIC, an FPGA or a combination thereof. For example, each function of the first remote-side control circuit 19 is realized by a processing circuit. For example, the functions of the first remote-side control circuit 19 are collectively realized by a processing circuit.

For each function of the first remote-side control circuit 19, a part thereof may be realized by the dedicated hardware 200, while the other parts may be realized by software or firmware. For example, the function of controlling opening/closing of the first switching element 14 may be realized by a processing circuit as the dedicated hardware 200, and functions other than the function of controlling opening/closing of the first switching element 14 may be realized by the at least one processor 100a reading and executing the program stored in the at least one memory 100b.

Thus, a processing circuit realizes each function of the first remote-side control circuit 19 by the hardware 200, software, firmware or a combination thereof.

Each function of the second remote-side control circuit 20 is also realized by a processing circuit equivalent to the processing circuit that realizes each function of the first remote-side control circuit 19, though it is not shown. Each function of the first master-side control circuit 22 is also realized by a processing circuit equivalent to the processing circuit that realizes each function of the first remote-side control circuit 19. Each function of the second master-side control circuit 23 is also realized by a processing circuit equivalent to the processing circuit that realizes each function of the first remote-side control circuit 19.

### INDUSTRIAL APPLICABILITY

As described above, the transmission system of the present disclosure can be used for an elevator system.

### REFERENCE SIGNS LIST

1 Hoistway, 2 Machine room, 3 Hall, 4 Traction machine, 5 Main rope, 6 Car, 7 Hall door, 8 Car door, 9 Safety apparatus, 10 Control apparatus, 11 Remote unit, 12 Master unit, 13 Cable, 14 First switching element, 15 Second switching element, 16 Signal output circuit, 16a Positive-side power supply, 16b Negative-side power supply, 17 Positive-side insulation signal element, 18 Negative-side insulation signal element, 19 First remote-side control circuit, 20 Second remote-side control circuit, 21 Signal separation circuit, 21a First separation element, 21b Second separation element, 22 First master-side control circuit, 23 Second master-side control circuit, 100a Processor, 100b Memory, 200 Hardware.

1. A transmission system comprising:
a remote unit alternately outputting pulse voltage with a positive polarity and pulse voltage with a negative polarity as a signal by causing a first switching element and a second switching element to alternately open and close; and
a master unit accepting input of a signal from the remote unit via a cable, and separating the signal into a first signal corresponding to the pulse voltage with the positive polarity and a second signal corresponding to the pulse voltage with the negative polarity,
wherein the signal from the remote unit is not normally restored in the master unit unless the first switching element and the second switching element in the remote unit normally open and close.

2. The transmission system according to claim 1, wherein
the remote unit comprises:
a first remote-side control circuit controlling opening/closing of the first switching element so that the first switching element and the second switching element alternately open and close; and
a second remote-side control circuit controlling opening/closing of the second switching element so that the first switching element and the second switching element alternately open and close.

3. The transmission system according to claim 2, wherein the first remote-side control circuit and the second remote-side control circuit monitor open/close states of the first switching element and the second switching element.

4. The transmission system according to claim 2, wherein
the first remote-side control circuit closes the first switching element when detecting that the second switching element has opened and, after a first operation time set in advance passes, opens the first switching element; and
the second remote-side control circuit closes the second switching element when detecting that the first switching element has opened and, after a second operation time set in advance passes, opens the second switching element.

5. The transmission system according to claim 4, wherein
the first remote-side control circuit maintains the first switching element in an opened state when an abnormality is detected; and
the second remote-side control circuit maintains the second switching element in an opened state when an abnormality is detected.

6. The transmission system according to claim 5, wherein
the master unit comprises:
a first master-side control circuit monitoring the first and second signals; and
a second master-side control circuit monitoring the first and second signals.

7. The transmission system according to claim 6, wherein the first master-side control circuit and the second master-side control circuit detect an abnormality if the first signal is not detected during a time obtained by adding a first spare time set in advance to the first operation time or if the second signal is not detected during a time obtained by adding a second spare time set in advance to the second operation time.

8. The transmission system according to claim 3, wherein
the first remote-side control circuit closes the first switching element when detecting that the second switching element has opened and, after a first operation time set in advance passes, opens the first switching element; and
the second remote-side control circuit closes the second switching element when detecting that the first switching element has opened and, after a second operation time set in advance passes, opens the second switching element.

9. The transmission system according to claim 8, wherein
the first remote-side control circuit maintains the first switching element in an opened state when an abnormality is detected; and
the second remote-side control circuit maintains the second switching element in an opened state when an abnormality is detected.

10. The transmission system according to claim 9, wherein
the master unit comprises:
a first master-side control circuit monitoring the first and second signals; and
a second master-side control circuit monitoring the first and second signals.

11. The transmission system according to claim 10, wherein the first master-side control circuit and the second master-side control circuit detect an abnormality if the first signal is not detected during a time obtained by adding a first spare time set in advance to the first operation time or if the second signal is not detected during a time obtained by adding a second spare time set in advance to the second operation time.

12. The transmission system according to claim 1, wherein
the remote unit is provided on a car of an elevator.

13. The transmission system according to claim 12, wherein
the master unit is provided in a control apparatus of the elevator.

14. The transmission system according to claim 1, wherein
the master unit is provided in a control apparatus of an elevator.
